(19) United States
(12) Patent Application Publication
(10) Pub. No.: US 2005/0031291 A1
(43) Pub. Date: Feb. 10, 2005

(54) Assembly of device components and sub-systems

(76) Inventors: Renfeng Gao, Downingtown, PA (US); Anthony F. Garito, Radnor, PA (US); Aydin Yeniay, Wayne, PA (US)

Correspondence Address: Brian M. Burn, Esq.;Min, Hsieh, & Hack LLP, c/o PortfolioIP, P.O. Box 52050, Minneapolis, MN, 55402, US

(21) Appl. No.: 10/807,470

(22) Filed: Mar. 24, 2004

Related U.S. Application Data
(60) Provisional application No. 60/477,348, filed on Jun. 11, 2003.
(60) Provisional application No. 60/456,555, filed on Mar. 24, 2003.

(51) Int. Cl. G02B 6/00; H01L 21/00; H01L 21/84

(52) U.S. Cl. 385/142

(57) ABSTRACT

An optical assembly has two mechanically matched substrates, each substrate including structures, such as circuits and circuit elements, that are in shapes complementary to the structures on the other substrate. At least one substrate includes a clipgate for at least one optical component.

This application claims benefit of priority to U.S. Provisional Patent Application No. 60/477,348, filed Jun. 11, 2003; U.S. Provisional Patent Application No. 60/456,555, filed Mar. 24, 2003; and U.S. patent application Ser. No. 10/218,693, filed Aug. 14, 2002.

Embodiments consistent with the present invention are directed to fabrication and assembly of electronic and photonic integrated circuits, and optical devices made thereby.

The fabrication and assembly of electronic and photonic integrated circuits made of polymeric materials continue to undergo rapid development for a wide range of integrated device components, sub-systems, and systems. Fabrication technologies are based on a broad range of processing methods including but not limited to multi-layer lithography, three dimensional “3-D”) lithography, molding, embossing, stamping, replicating, and direct machining. Individual circuits are comprised of a plurality of circuit elements formed into simple or complex arrays and patterns. Such circuits can operate alone or together.

Of special interest are circuits assembled in various combinations with other circuits to provide greater flexibility or robustness in device component or sub-systems design and function. Thus, it is highly desirable to develop new, innovative methods for assembling otherwise individual circuits and circuit elements into two dimensional “2-D”) or 3-D component or sub-system arrays and architectures. Such methods would prove novel and advantageous for device and sub-system design, fabrication, operation, performance, and reliability.

### SUMMARY OF THE INVENTION

The present invention is directed to an optical assembly comprising two mechanically matched substrates. On each of the two substrates are located structures, wherein the structures on one substrate comprise shapes complementary to the structures on the other substrate. In addition, at least one substrate comprises one or more clipgates for an optical component. A clipgate, which has also been referred to as a trench, is defined as a channel formed on a substrate, usually in a u-groove type of pattern, in which an optical component can be placed.

Embodiments consistent with the present invention concern a “flip-chip” like assembly of two mechanically matched wafers with each wafer containing individual circuits and circuit elements. By use of the phrase “flip-chip” like assembly, it is understood that the circuits and circuit features on one solid substrate are formed in shapes complementary to the shapes of the circuits and circuit features located on a second solid substrate.

The present invention is also directed to fabricating such assemblies using a novel processing technique. For example, integrated optical circuits can be mechanically assembled by bringing the two substrates into face-to-face configuration such that each of the respective complementary circuits and circuit features are aligned. Once the complementary shaped structures, e.g., circuits and circuit elements, are aligned and physically contacted, the two substrates are pressed together to achieve a “snap-fit” like arrangement.

According to other aspects of the invention, there is provided a clip-on multi-functional integrated optical circuit comprising, on a passive waveguide substrate, at least one active component.

According to another aspect of the invention, there is provided a method of making a clip-on multifunctional integrated optical circuit comprising, on a passive waveguide substrate, at least one active component. The method comprises (a) fabricating the passive waveguide substrate, (b) etching desired shapes into the substrate, placing the at least one active component into the etched area (b), and positioning in alignment said at least one active component with the passive waveguide substrate.

According to other aspects of the invention, there is provided a planar optical wave guide. The waveguide comprises a substrate having a top surface, a first end, and a first channel extending from the first end toward the second end along the top surface. The first channel has a first sidewall extending toward the second end, a second sidewall extending toward the second end, and an endwall engaging the first sidewall and the second sidewall. A cladding layer is disposed on the top surface of the substrate. A core is disposed within the cladding layer. The core has a first end generally co-planar with the endwall and a second end.

According to other aspects of the invention, there is provided an optical waveguide assembly. The assembly comprises a planar waveguide including a substrate having a top surface, a first end, and a first channel extending from the first end toward the second end along the top surface. The first channel has a first sidewall extending toward the second end, a second sidewall extending toward the second end, and an endwall engaging the first sidewall and the second sidewall. A cladding layer is disposed on the top surface of the substrate and a core is disposed within the cladding layer. The core has a first end generally co-planar with the endwall and a second end. The assembly further comprises a first optical fiber disposed in the first channel. The first optical fiber has a first free end. The first optical fiber is comprised of a cladding and a fiber core disposed within the cladding. The fiber core is in optical alignment with the first end of the waveguide core.

According to a further aspect of the invention, there is provided a method of manufacturing a planar optical waveguide. The method comprises providing a generally planar substrate having a first end, a second end, and a top surface; forming a channel in the top surface extending from the first end toward the second end; disposing a first cladding material onto the top surface; forming a core on the first cladding material, the core having a first end optically aligned with the channel; and disposing a second cladding material over the core.

Certain aspects of the invention also relate to a method of manufacturing an optical waveguide assembly. The method comprises providing a planar optical waveguide including a substrate having a top surface, a first end, an opposing second end, and a first channel extending from the first end toward the second end along the top surface, the first channel having a first sidewall extending toward the second end, a second sidewall extending toward the second end, and an endwall engaging the first sidewall and the second sidewall; a cladding layer disposed on the top surface of the substrate; and a core disposed within the cladding layer, the core having a first end generally co-planar with the endwall and a second end. The method further comprises disposing a first optical fiber in the first channel, the first optical fiber having a first free end, the first optical fiber being comprised of a cladding and a fiber core disposed within the cladding, the fiber core being in optical alignment with the first end of the waveguide core.

According to one embodiment, there is provided an optical assembly comprising a first substrate comprising a first surface comprising at least a first structure and at least a first alignment feature; a second substrate comprising a first surface comprising at least a second structure complementary to each of the at least first structures and at least a second alignment feature complementary to each of the at least first alignment features; and a device mounted to at least one of the first surface of the first substrate and the first surface of the second substrates, the device selected from one of a photonic device, an electrical device, and a mechanical device.

According to another embodiment, there is provided an optical assembly comprising a first substrate comprising a first device; and a second substrate comprising a first surface comprising a first recess, wherein a surface geometry of the first recess of the second substrate is complementary to the first surface of the first substrate, and a second device, wherein contacting the first substrate to the second substrate permits the first surface of the first substrate to fit into the first recess of the second substrate and permits the first device to be aligned with the second device, and further wherein the first and second devices are chosen from photonic devices, electrical devices, and mechanical devices.

According to another embodiment, there is provided an optical assembly comprising a first chip comprising a first surface comprising a first locator and a first device; a first chip sub-mount comprising a second surface comprising a second locator and a second device, wherein the first surface of the first chip fits into a recess in the second surface of the sub-mount when the first locator contacts the second locator.

According to another embodiment, there is provided a method of making an integrated optical assembly comprising: forming a first structure and a first alignment feature on a first substrate; forming a second structure and a second alignment feature on a second substrate, wherein the second structure and the second alignment feature are complementary in shape to the first structure and the first alignment feature, respectively, on the first substrate; positioning a first device on the first substrate; positioning a second device on the second substrate; and contacting the first alignment feature of the first substrate to the second alignment feature of the second substrate thereby permitting the first device on the first substrate to be aligned with the second device on the second substrate.

According to another embodiment, there is provided an optical assembly comprising: a first and a second mechanically matched substrates, each substrate comprising structures, wherein the structures on one substrate comprise shapes complementary to the structures on the other substrate, wherein at least one substrate comprises one or more clipgates for an optical component.

According to yet another embodiment, there is provided a method of making an integrated optical assembly, said method comprising: (a) fabricating structures on a first substrate; (b) fabricating structures on a second substrate in shapes complementary to the structures on the first substrate, wherein at least one of said first and second substrates comprise a clipgate for an optical component; (c) mechanically positioning an optical component in said clipgate; (d) bringing said first and second substrates into face-to-face configuration such that the complementary shaped structures are aligned; (e) physically contacting said first and second substrates; and (f) pressing the said first and second substrates together.

### BRIEF DESCRIPTION OF THE DRAWINGS

The accompanying drawings, which are incorporated in and constitute a part of this specification, illustrate embodiments of the invention and together with the description, serve to explain the principles of the invention. In the drawings:

FIG. 1 shows an optical assembly according to various embodiments.

FIG. 2a shows an exemplary structure according to various embodiments.

FIG. 2b shows another exemplary structure according to various embodiments.

FIG. 2c shows another exemplary structure according to various embodiments.

FIG. 2d shows another exemplary structure according to various embodiments.

FIG. 3 shows exemplary structures comprising devices.

FIG. 4 shows an exemplary chip comprising various devices and structures according to various embodiments.

FIG. 5 shows a flow chart for the design of a chip and a sub-mount according to various embodiments.

FIG. 6 shows a flow chart for setting physical tolerances for fabrication of components according to various embodiments.

FIG. 7a shows a representative exploded view of an optical assembly according to some embodiments of the invention.

FIG. 7b shows another representative optical assembly according to some embodiments of the invention.

FIG. 8a shows another representative optical assembly according to some embodiments of the invention.

FIG. 8b shows another representative optical assembly according to some embodiments of the invention.

### DESCRIPTION OF THE EMBODIMENTS

Reference will now be made in detail to the present embodiments, examples of which are illustrated in the accompanying drawings.

In accordance with the present invention, there is provided an optical assembly comprising two mechanically matched substrates, each substrate comprising devices, such as photonic devices, electrical devices, and mechanical devices. At least one substrate can comprise one or more structures, such as clipgates, trenches, and/or recesses and projections. The structures can accommodate various devices, such as photonic devices, electronic devices, and/or mechanical devices. Photonic devices can include, for example, an optical fiber, a waveguide, a laser, a grating, a transmitter, a lens, a thin film filter, a prism, a polarizer, an isolator, or a detector. Further, the at least one substrate and/or structures can comprise electronic devices, such as circuits and circuit elements. And still further, the at least one substrate and/or structures can comprise mechanical devices, such as MEMS or MOEMS.

In accordance with the present invention, there is also provided various methods of making an integrated optical assembly structure. A method according to the various embodiments can comprise: (a) fabricating structures on a first substrate; (b) fabricating structures on a second substrate in shapes complementary to the structures on the first substrate, wherein at least one of the first and second substrates comprise a clipgate for a photonic device; (c) mechanically positioning a photonic device in the clipgate; (d) bringing the first and second substrates into face-to-face configuration such that the complementary shaped structures are aligned; (e) physically contacting the first and second substrates; (f) pressing the first and second substrates together to achieve a snug fit; and optionally, (g) providing a mechanical holding device, or adhesive bonding.

The structures, that can be on or in the substrates, can be fabricated by a broad range of processing methods including, but not limited to, multi-layer lithography, 3D lithography, molding, embossing, stamping, replicating, and direct machining, either alone or in combinations. Fabrication methods based on molding, embossing, stamping, or replicating usually require a master mold, which can be formed by lithographic techniques and then used directly or indirectly in the selected fabrication method.

Similarly, each substrate can include alignment features, such as recesses and projections, that can be used for locating and accurately positioning the substrates together. Alignment features can take a variety of geometrical shapes and forms such as dots, rails, or blocks, having different cross-sections. Further, a variety of alignment features can be implemented. Alignment features can be formed by methods similar to those used to form the structures described above. Alignment features can also be formed by techniques known to one of ordinary skill in the art.

Various embodiments can provide an efficient photonic chip/module assembly based on passive alignment for single mode and multimode optical waveguide devices.

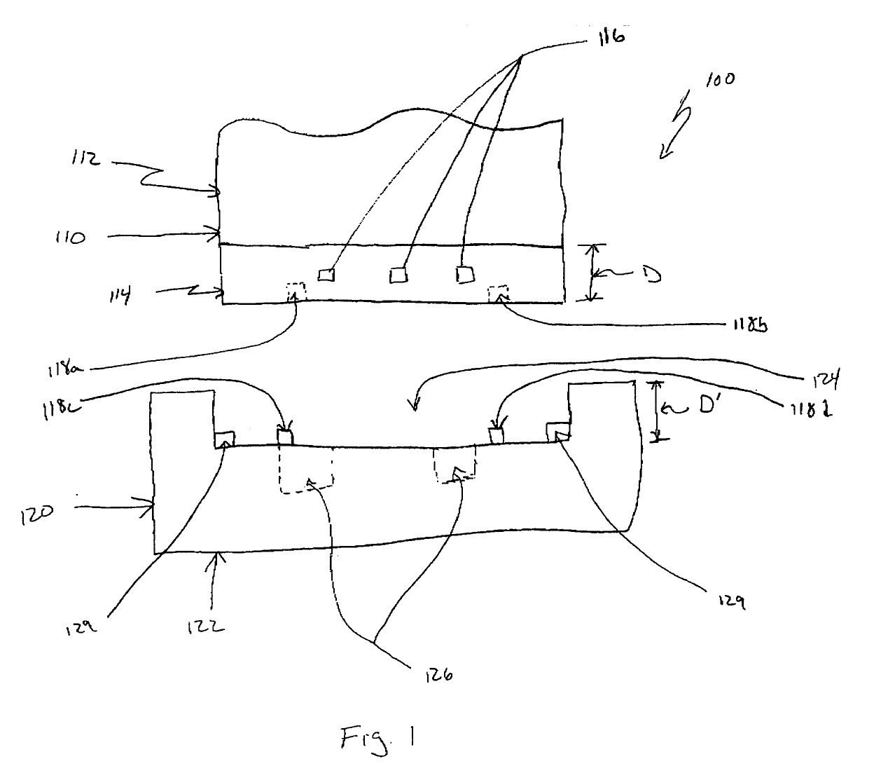

FIG. 1 shows an exemplary optical assembly 100 in an exploded view. Optical assembly 100 can comprise a chip 110 formed from a substrate 112, and a component area 114. For ease of description, in some instances, component area 114 can be referred to as a surface of the chip. Chip 110 can comprise a photonic chip that includes photonic devices, an electronic chip that includes electronic devices, and/or a mechanical chip that includes mechanical devices. In various embodiments, chip 110 can include any and all of a photonic chip, an electronic chip, and a mechanical chip. Component area 114 can include the various devices as may be desired by the particular application. For example, in the case of a photonic chip, the component area 114 can include waveguide circuits 116, or other photonic devices. Chip 110 also can comprise at least one alignment feature 118a and 118b, and optionally, structures (not shown).

The exemplary optical assembly 100 can also include a sub-mount (also called a chip sub-mount) formed on or in a substrate 122. Sub-mount 120 can comprise a photonic chip sub-mount that includes photonic devices, an electronic chip sub-mount that includes electronic devices, and/or a mechanical chip sub-mount that includes mechanical devices. In various embodiments, sub-mount 120 can include any and all of a photonic chip sub-mount, an electronic chip sub-mount, and a mechanical chip sub-mount. Further, sub-mount 120 can include a recessed area 124. Recessed area 124 can be formed such that it accurately accommodates the surface geometry of component area 114. Sub-mount 120 can also comprise structures 126 in which devices can be mounted. Further, sub-mount 120 can also comprise alignment features 118c and 118d that are complementary to alignment features 118a and 118d, respectively. Sub-mount 120 can also comprise spacers 129 that can be used to prevent harm coming to devices of chip 110 and/or sub-mount 120 when optical assembly 100 is completed. For example, spacers 129 can create a predetermined separation between chip 110 and sub-mount 120, thereby protecting the various devices from being crushed upon assembly. Optionally, spaces can be formed on chip 110 or on both chip 110 and sub-mount 120.

Optical assemblies as disclosed herein can be manufactured to have high precision. In an exemplary embodiment, alignment tolerances can be on the order of <0.1 to 1.0 microns. These superior alignments can be achieved in contrast to conventional systems because conventional systems use active alignment, which is when each component of an assembly is aligned by measuring the optical performance on a test bed to optimize the alignment position. In contrast, various embodiments of optical assemblies described herein can be accurately aligned by using a flip-chip assembly of the chip and sub-mount.

For example, as shown in FIG. 1, component area 114 can be fabricated to have a thickness D of, for example, 10 microns ±0.2 microns. Further, recessed area 124 can have a thickness D′of, for example, 10 microns ±0.2 microns. As such, when chip 110 is brought into contact with sub-mount 120, the alignment tolerance can be within an order of tens of microns. Using methods consistent with those described herein, even better alignment tolerances can be achieved.

Chips and sub-mounts can be fabricated by a variety of manufacturing techniques and from numerous optical materials such as glasses, polymers, semiconductors, metals, and composite materials, either singly or in combination.

As will be described more fully below, multiple chips can be combined with multiple sub-mounts and post-assembly steps can be used in processing optical assemblies. For example, the assembly structure may be cut, sliced, or diced to fabricate a plurality of isolated individual assemblies. The advantages of this procedure are numerous, including, for example, obviating the need for additional costly process steps such as mechanically preparing optically compliant end faces for each diced component.

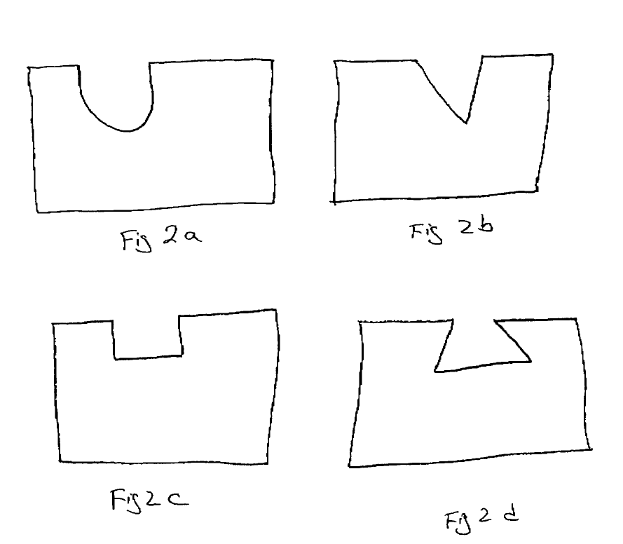

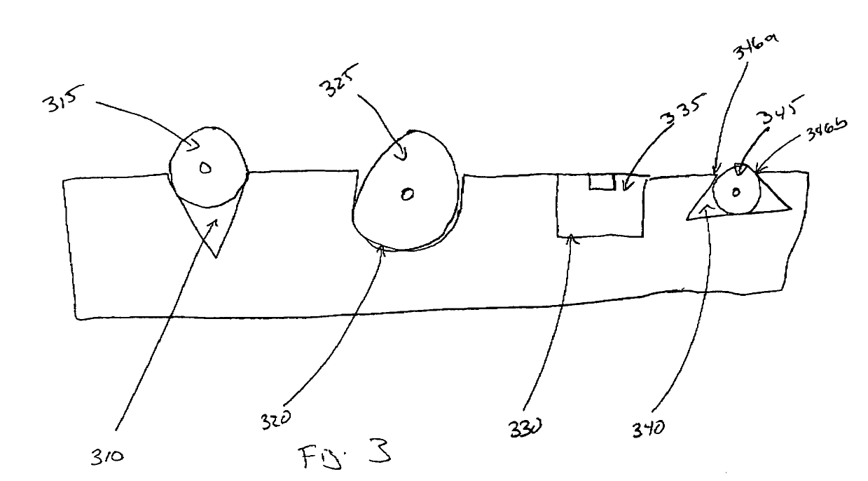

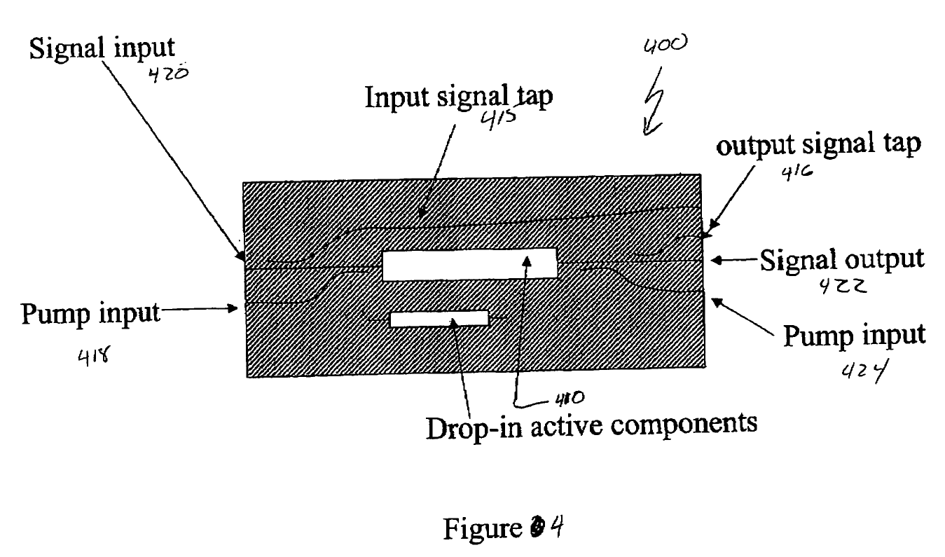

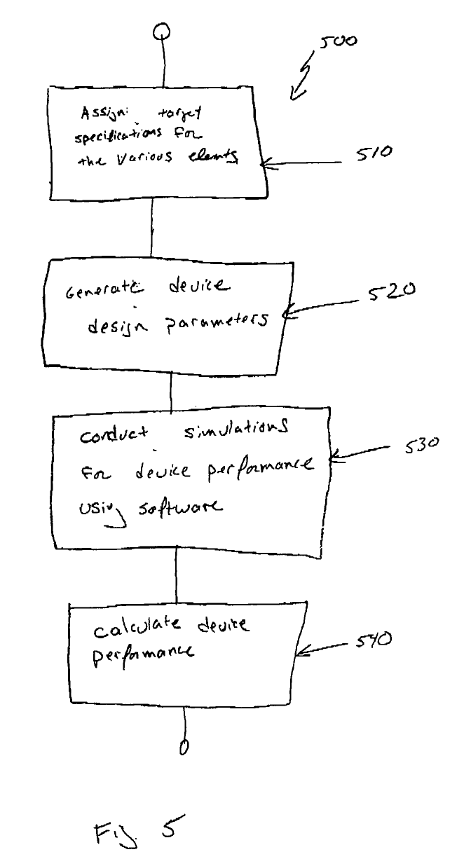

According to various embodiments, structures can be fabricated on chips and/or sub-mounts. Devices, such as photonic devices, electronic devices, and/or mechanical devices can be disposed, by dropping, for example, into the structures. Further, structures can be formed into a variety of shapes. For example, FIGS. 2a-2d show exemplary structures having, as shown in FIG. 2a parallel pipes shapes (also called U-grooves), FIG. 2b V-grooves, FIG. 2c rectangular grooves, or FIG. 2d trapezoidal grooves. In the exemplary embodiment of FIG. 2d, an optical fiber set in the trapezoidal can be securely fixed by the top angles of the structure. Other shapes, such as elliptical, circular, or any other shape can be used for the structures. The structures can be fabricated by various methods that include, for example, plasma etching, wet etching, molding, stamping, printing, or embossing. As mentioned, after the structures are fabricated, various devices, such as photonic, electronic, and/or mechanical devices, can be disposed on or in the structure as schematically diagrammed in FIG. 3. FIG. 3 shows a V-groove 310 comprising an optical fiber 315, a U-groove 320 comprising an optical fiber 325, a rectangular groove 330 comprising a waveguide 335, and a trapezoidal groove 340 comprising an optical fiber 345 secured by the top angles 346a and 346b of the structure.

According to various embodiments, structures of the chip can be of a complementary shape as structures of the sub-mount. In this manner, the alignment between the structures and the devices assists in proper optical alignment between the various devices. Further, correctly contacting the alignment features of one substrate with the alignment features of another substrate permits the device of one substrate to be accurately aligned with the devices of other substrates.

FIG. 4 depicts a chip 400 containing structures and, disposed therein, devices that can be dropped-in, such as, for example, an optical amplifier. Optical couplers and taps 415 and 416 can be fabricated on chip 400 along with a structure, such as a clipgate. A high gain doped glass, such as erbium doped glass, optical fiber approximately 1-5 cm in length is then dropped into the clipgate and, according to certain aspects of the invention, thereby automatically optically aligned. The chip may also comprise other devices, such as a pump input 418, a signal input 420, a signal output 422, and a pump input 424.

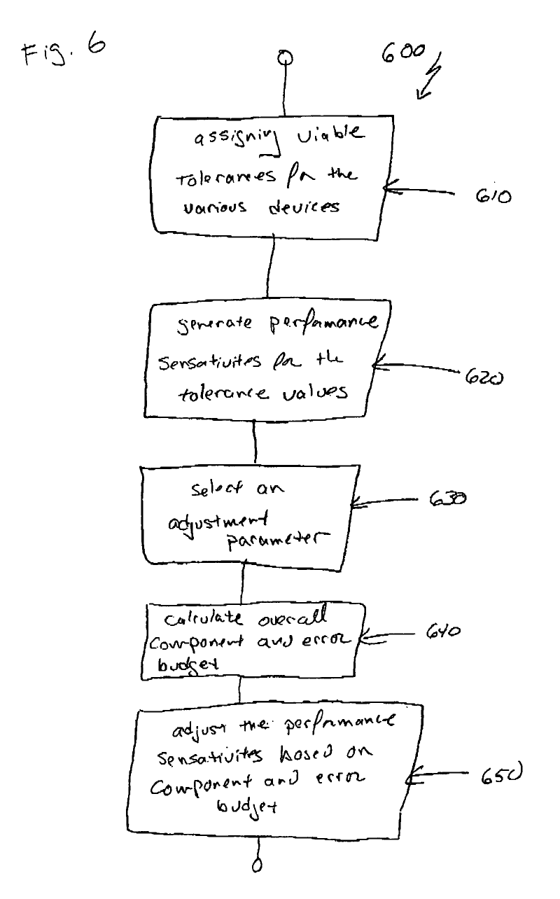

FIG. 5 shows a flowchart 500 for the design of a chip and a sub-mount. The design of the chip and sub-mount comprises the steps of assigning target specifications for all the elements, shown at 510; generating device design parameters, shown at 520; conducting simulations for device performance using a software code generated for that purpose, shown at 530; and calculating overall device performance and extreme conditions for performance, shown at 540.

FIG. 6 shows a flowchart 600 for setting the physical tolerances for photonic devices, electrical devices, and mechanical devices. The setting of physical tolerances comprises the steps of assigning viable tolerances for photonic, electrical, and mechanical devices, shown at 610; generating performance sensitivities for the tolerance values, shown at 620; selecting an adjustment parameter, shown at 630; calculating overall component and error budget, shown at 640; and tightening or loosening the performance sensitivities based on the component and error budget, shown at 650.

An exemplary method according to various embodiments will now be described. A photonic device, e.g., a waveguide, can be fabricated by replication patterning. A waveguide master stamper can be first fabricated, and then used to fabricate a plurality of UV transparent replicas for the master. Alternatively, a solid substrate can be coated with curable monomer/polymer liquid composition and a stamper applied to the substrate to form the waveguide pattern. The substrate is then exposed to UV radiation to cure the waveguide pattern, and the stamper subsequently removed from the solid substrate. Finally, the waveguide pattern can be inspected and tested.

According to various embodiments, there is provided an integrated optical assembly having various components, including a chip sub-mount and a chip. In this embodiment, the various devices and elements can be mechanically positioned within the designated structures. Next, the chip sub-mount can be mechanically positioned such that the chip sub-mount and the chip are brought into face-to-face configuration. After the chip sub-mount and the chip are mechanically aligned and physically contacted, they can be pressed together for a “snug-fit.” In some embodiments, the combined assembly, comprising the chip sub-mount and chip, can be secured together mechanically with a yoke or any other suitable binding structure. Alternatively, the assembly may be held together with a bonding material or encased in an encasement.

According to various embodiments, there is provided an integrated optical assembly comprising various components including a photonic sub-mount and a photonic chip providing photonic functionality. In this embodiment, the devices are mechanically positioned within the designated structures. Next, the photonic chip sub-mount is mechanically positioned within the designated structures. Next, the photonic chip sub-mount is mechanically positioned such that the photonic chip sub-mount and the photonic chip are brought into face-to-face configuration.

According to various embodiments, there is provided an integrated optical assembly comprising various components including a photonic sub-mount and a chip providing electronic functionality. In this embodiment, the devices are mechanically positioned within the designated structures. Next, the photonic chip sub-mount is mechanically positioned within the designated structures. Next, the photonic chip sub-mount is mechanically positioned such that the photonic chip sub-mount and the electronic chip are brought into face-to-face configuration.

According to various embodiments, there is provided an integrated optical assembly comprising various components including a photonic sub-mount and a chip providing mechanical functionality. In this embodiment, the devices are mechanically positioned within the designated structures. Next, the photonic chip sub-mount is mechanically positioned within the designated structures. Next, the photonic chip sub-mount is mechanically positioned such that the photonic chip sub-mount and the mechanical chip are brought into face-to-face configuration.

In the above exemplary embodiments, the chip can provide in any combination the three functionalities, namely photonic, electronic, and mechanical functionalities (such as MEMS and MOEMS chips). Further, the sub-mount can provide in any combination the three functionalities, namely photonic, electronic, and mechanical functionalities.

Planar Optical Waveguides

Chips and sub-mounts can be fabricated by a variety of manufacturing techniques and from numerous optical materials such as glasses, polymers, semiconductors, metals, and composite materials, either singly or in combination.

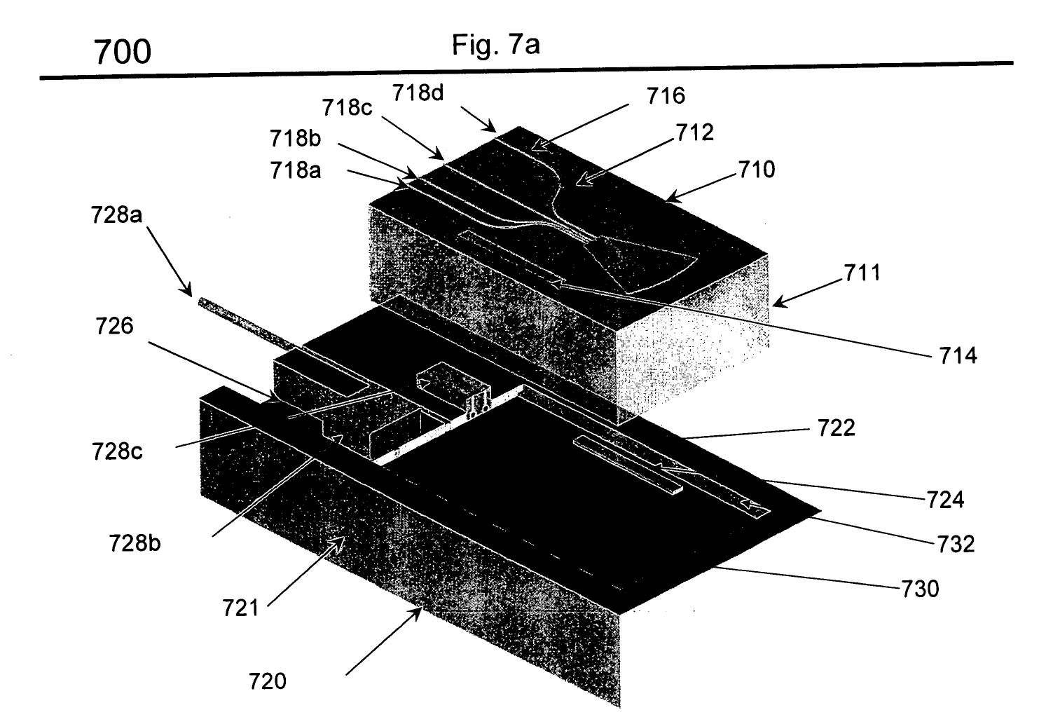

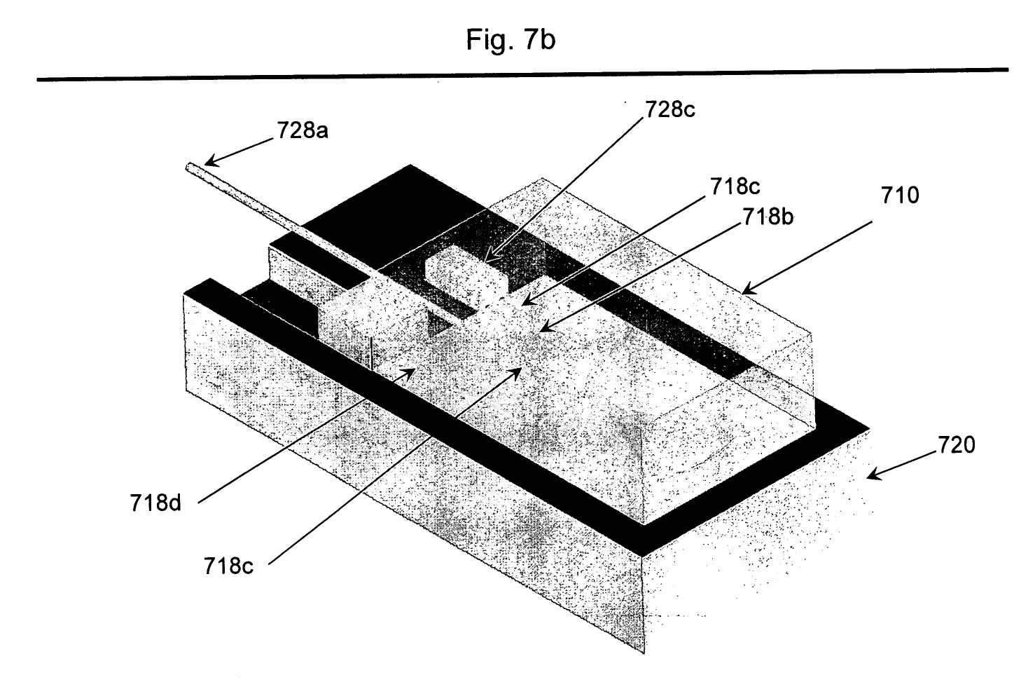

FIG. 7a shows an exemplary assembly 700 according to various embodiments. Assembly 700 can comprise a chip 710, such as a photonic chip, electronic chip, and/or a mechanical chip, comprising a generally planar substrate 711 and a chip sub-mount 720, such as a photonic chip sub-mount, electronic chip sub-mount, and/or mechanical chip sub-mount, comprising a sub-mount substrate 721. Suitably, the substrates 711 and 721 can be constructed from a plastic, such as polycarbonate, acrylic, polymethyl methacrylate, cellulosic, thermoplastic elastomer, ethylene butyl acrylate, ethylene vinyl alcohol, ethylene tetrafluoroethylene, fluorinated ethylene propylene, polyetherimide, polyethersulfone, polyetheretherketone, polyperfluoroalkoxyethylene, nylon, polybenzimidazole, polyester, polyethylene, polynorbornene, polyimide, polystyrene, polysulfone, polyvinyl chloride, polyvinylidene fluoride, ABS polymers, polyacrylonitrile butadiene styrene, acetal copolymer, poly[2,2-bistrifluoromethyl-4,5-difluoro-1,3-dioxole-co-tetraf-luoroethylene] (sold under the trademark TEFLON® AF), poly[2,3-(perfluoroalkenyl) perfluorotetrahydrofuran] (sold under the trademark CYTOP.RTM.), poly[2,2,4-trifluoro-5-trifluoromethoxy-1,3-dioxol-e-co-tetrafluoroethylene] (sold under the trademark HYFLON®), and any other thermoplastic polymers; and thermoset polymers, such as diallyl phthalate, epoxy, furan, phenolic, thermoset polyester, polyurethane, and vinyl ester. However, those skilled in the art will recognize that a blend of at least two of the polymers listed above, or other polymers, can be used. Although substrates 711 and 721 can be suitably constructed from a polymer, those skilled in the art will recognize that the substrates can be constructed from other materials, such as silicon, glass, semiconductor metals, or composites.

In an exemplary embodiment, an undercladding can be disposed on the top surface of the substrate 711. Suitably, the undercladding can be constructed from an optical polymer, although those skilled in the art will recognize that other materials, such as optical glasses, semiconductors, or composites can be used. In various embodiments, the undercladding can be approximately between 10 and 20 microns thick, although those skilled in the art will recognize that the undercladding can be other thicknesses as well.

A core is disposed on a portion of the undercladding. Those skilled in the art will recognize that the core can be generally straight or curved. Suitably, the core can be constructed from an optical polymer, although those skilled in the art will recognize that other materials, such as optical glasses, semiconductors, or composites can be used. In various embodiments, the core is approximately between 3 and 10 microns thick, although those skilled in the art will recognize that the core can be other thicknesses as well.

An overcladding is disposed on the core and the portion of the undercladding not covered by the core, such that the core is generally surrounded by the undercladding and the overcladding. Suitably, the overcladding can be constructed from an optical polymer, although those skilled in the art will recognize that other materials, such as optical glasses, semiconductors, or composites can be used. In various embodiments, the overcladding can be approximately between 10 and 20 microns thick, although those skilled in the art will recognize that the overcladding can be other thicknesses as well.

Continuing with the discussion of the exemplary embodiment shown in FIG. 7a, there is the optical assembly 700 prior to final assembly. Optical assembly, including chip 710, comprises substrate 711 comprising a surface 712 of a predetermined geometry, an alignment feature 714, a plurality of structures 716 having a plurality of devices, such as optical fibers 718a, 718b, 718c, and 718d and other devices 718e. As shown in FIG. 7a, the surface 712 has structures 716, such as trenches formed therein. The structures can be realized by fabrication technologies that are based on a broad range of processing methods including but not limited to multi-layer lithography, three-dimensional “3-D”) lithography, molding, embossing, stamping, replicating, and direct machining. Individual circuits are comprised of a plurality of circuit elements into simple or complex arrays and patters. Such circuits can operate alone or together. Optical fibers can be securely disposed in the structures. In the example shown in FIG. 7a, alignment feature 714 may be a protrusion having a predefined size and shape, such as a rectangle, however any other predetermined shape can be used.

FIG. 7a also shows a first sub-mount 720, comprising the sub-mount substrate 721 comprising a surface 722, an alignment feature 724, a plurality of structures 726 having a plurality of devices, such as optical fiber 728a, a transmitter 728b, and a receiver 728c. As shown in FIG. 7a, optical fiber 728a, transmitter 728b, and receiver 728c can be dropped into a structure, such as structure 726.

In the example shown in FIG. 7a, alignment feature 724 is the complementary shape to alignment feature 714. For example, when alignment feature 714 is a protrusion of a predetermined size and shaped rectangle, alignment feature 724 can be a recess of similar size and shape as that of alignment feature 714, only in the converse.

In various embodiments, substrate 721 includes a recess 730. In this embodiment, the surface geometry of recess 730 is designed to accurately accept chip 710. To accurately align chip 710 into sub-mount 720, alignment feature 714 can be correctly positioned to contact alignment feature 724. For example, alignment feature 714 can be physically aligned and inserted into alignment feature 724. Further, recess 730 can include a spacer 732. Spacer 732 can be used to prevent harm coming to devices of chip 710 and/or sub-mount 720 when optical assembly 700 is completed. For example, spacers 732 can create a predetermined separation between chip 710 and sub-mount 720, thereby protecting the various devices from being crushed upon assembly.

As shown in FIG. 7b, by such alignment, surface 714 of chip 710 can accurately fit into recess 730 of sub-mount 720. In this way, for example, optical fibers 718a and 718b are accurately aligned with receiver 728c. Similarly, proper location of alignment features 714 and 724 accurately aligns optical fibers 718c with optical fiber 728a, and 718d with transmitter 728b. Additionally, chip 710 mounted to sub-mount 720 protects the aligned devices. In various embodiments, assembly 700 can be fastened together with a yoke (not shown) or the like.

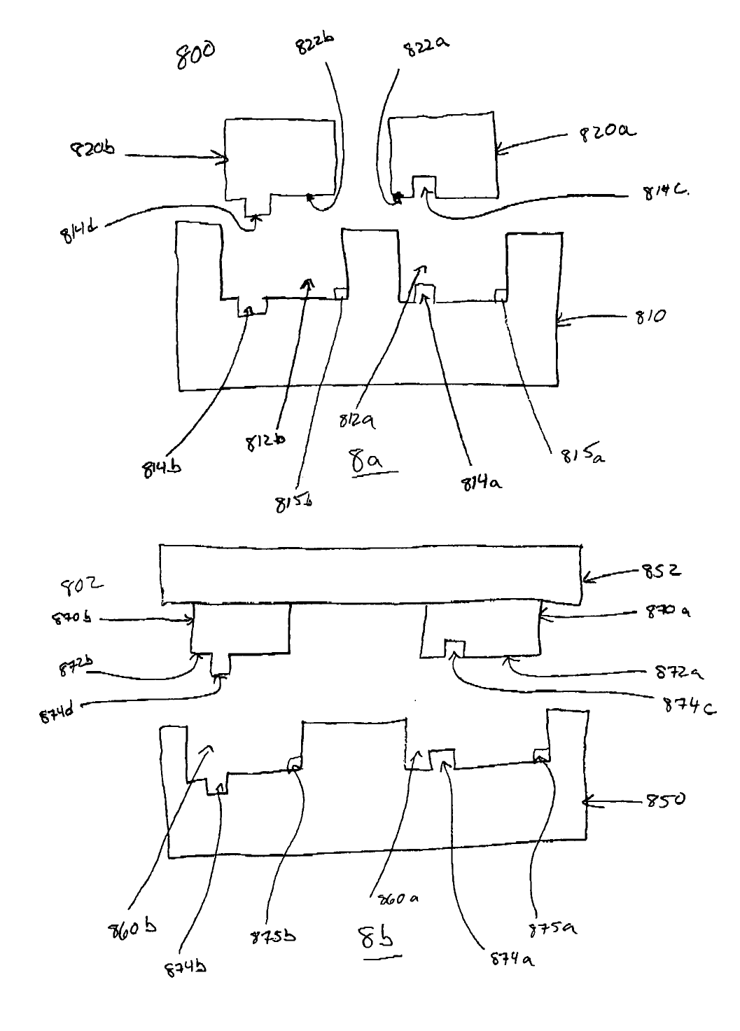

FIG. 8a shows an exemplary optical assembly 800 according to another embodiment. Optical assembly 800 comprises a chip sub-mount 810, such as a photonic chip sub-mount, an electronic chip sub-mount, and/or a mechanical chip sub-mount, comprising a plurality of recesses 812a and 812b. Further, recesses 812a and 812b can include alignment feature 814a and 814b, spacers 815a and 815b, and devices (not shown). FIG. 8a also shows a plurality of chips 820a and 820b, such as a photonic chip, electronic chip, and/or a mechanical chip, comprising surfaces 822a and 822b, respectively, and devices (not shown). Each of chips 820a and 820b can also include an alignment feature 814c and 814d. Proper location of alignment features 814a and 814c aligns devices of chip 820a with devices of chip sub-mount 810. Proper location of alignment features 814b and 814d aligns devices of chip 820b with devices of chip sub-mount 810. In this manner, multiple chips can be accurately aligned with chip sub-mount 810.

FIG. 8b shows an exemplary optical assembly 802 according to another embodiment. Optical assembly 802 comprises a chip sub-mount 850 such as a photonic chip sub-mount, an electronic chip sub-mount, and/or a mechanical chip sub-mount, comprising a plurality of recesses 860a and 860b. Further, recesses 860a and 860b can include an alignment feature 874a and 874b, spacers 875a and 875b, and devices (not shown). In some embodiments, chip sub-mount 850 can be mounted on a sub-mount substrate (not shown). In various embodiments, assembly 800 can be fastened together with a yoke (not shown).

FIG. 8b also shows a plurality of chips 870a and 870b, such as a photonic chip, an electronic chip, and/or a mechanical chip, comprising surfaces 872a and 872b, respectively, and devices (not shown). Each of chips 870a and 870b can also include an alignment feature 874c and 874d. Proper location of alignment features 874a and 874c aligns devices of chip 870a with devices of chip sub-mount recess 860a. Proper location of alignment features 874b and 874d aligns devices of chip 870b with devices of chip sub-mount recess 860b. In this manner, multiple chips can be accurately aligned with chip sub-mount 850. Subsequent to forming combined optical assemblies by contacting the photonic chips onto the photonic chip sub-mounts, individual optical assemblies can be cut from the combined structure.

Other embodiments will be apparent to those skilled in the art from consideration of the specification and practice of the embodiments disclosed herein. It is intended that the specification and examples be considered as exemplary only, with a true scope and spirit of the invention being indicated by the following claims.

1. An optical assembly comprising:
a first substrate comprising a first surface comprising at least a first structure and at least a first alignment feature;
a second substrate comprising a first surface comprising at least a second structure complementary to each of the at least first structures and at least a second alignment feature complementary to each of the at least first alignment features; and
a device mounted to at least one of the first surface of the first substrate and the first surface of the second substrates, the device selected from one of a photonic device, an electrical device, and a mechanical device.

2. An optical assembly according to claim 1, wherein the first surface of the first substrate is in physical contact with the first surface of the second substrate such that each of the first alignment features and each of the corresponding second alignment features are in contact thereby permitting each of the at least first structures to be physically aligned with each of the corresponding complementary at least second structures.

3. An optical assembly according to claim 2, wherein the first substrate comprises a chip and the second substrate comprises a chip sub-mount, wherein the chip secures together with the chip sub-mount.

4. An optical assembly according to claim 2, wherein the first substrate comprises a photonic chip and the second substrate comprises a photonic chip sub-mount wherein the photonic chip secures together with the photonic chip sub-mount.

5. An optical assembly according to claim 2, wherein the first substrate comprises an electronic chip and the second substrate comprises an electronic chip sub-mount, wherein the electronic chip secures together with the electronic chip sub-mount.

6. An optical assembly according to claim 2, wherein the first substrate comprises a mechanical chip and the second substrate comprises a photonic chip sub-mount, wherein the photonic chip secures together with the photonic chip sub-mount.

7. An optical assembly according to claim 3, wherein the chip and the chip sub-mount comprise at least one photonic device chosen from a fiber, a waveguide, a waveguide chip, a laser, a grating, a transmitter, and a detector and wherein the chip sub-mount further comprises at least one electrical device chosen from circuits and circuit elements.

8. An optical assembly according to 3, wherein the chip sub-mount further comprises at least one electrical device chosen from circuits and circuit elements.

9. An optical assembly according to claim 3, wherein at least one of the at least first structures comprises a trench, and wherein a first photonic device is disposed in the trench, and wherein the second substrate comprises the device, such that when the chip and the chip sub-mount are secured together, the photonic device disposed in the trench is aligned with device of the second substrate.

10. An optical assembly according to claim 3, wherein at least one of the at least second structures comprises a trench, and wherein the device is disposed in the trench, and wherein the first substrate comprises a photonic device, such that when the chip and the chip sub-mount are secured together, the device disposed in the trench is aligned with the photonic device of the first substrate.

11. An optical assembly according to claim 9, wherein the trench has a profile selected from a U-shape, a V-shape, a rectangular shape, and a trapezoidal shape.

12. An optical assembly according to claim 10, wherein the trench has a profile selected from a U-shape, a V-shape, a rectangular shape, and a trapezoidal shape.

13. An optical assembly according to claim 3, wherein at least one of the at least first structures comprises a first trench, and wherein a first photonic device is disposed in the first trench, and wherein the second substrate comprises a second trench, and wherein the device is disposed in the second trench, such that when the chip and the chip sub-mount are secured together, the photonic device disposed in the first trench is aligned with device disposed in the second trench.

14. An optical assembly according to claim 3, wherein the second structure of the second substrate has a recessed geometry that is complementary to a surface geometry of the first structure of the first substrate, wherein the first structure fits into the second structure of the second substrate, and further wherein the first substrate includes at least a photonic device and the second substrate includes the device, and further wherein when the first structure fits into the second structure, the photonic device is aligned with the device of the second substrate.

15. An optical assembly according to claim 3 further comprising:
a plurality of photonic chips secured to the photonic chip sub-mount.

16. An optical assembly according to claim 1, wherein the first substrate comprises a plurality of chips and the second substrate comprises a plurality of chip sub-mounts.

17. An optical assembly comprising:
a first substrate comprising a first surface comprising a first device; and
a second substrate comprising a first surface comprising a first recess, wherein a surface geometry of the first recess of the second substrate is complementary to the first surface of the first substrate, and a second device, wherein contacting the first substrate to the second substrate permits the first surface of the first substrate to fit into the first recess of the second substrate and permits the first device to be aligned with the second device, and further wherein the first and second devices are chosen from photonic devices, electrical devices, and mechanical devices.

18. An optical assembly according to claim 17, wherein the first alignment feature is chosen from one of recesses and projections.

19. An optical assembly according to claim 17, wherein the first device is mounted in a trench in the first surface of the first substrate.

20. An optical assembly according to claim 17, wherein the photonic devices are chosen from a fiber, a waveguide, a waveguide chip, a laser, a grating, a transmitter, a detector and wherein the electrical devices are chosen from circuits and circuit elements.

21. An optical assembly according to claim 17 wherein the first surface comprises a first alignment feature and wherein the second surface comprises a second alignment feature complementary to the first alignment feature.

22. An optical assembly according to claim 17 wherein the recess includes a spacer.

23. An optical assembly according to claim 17, wherein the second substrate comprises a plurality of recesses, wherein each of the plurality of recesses comprises an alignment feature and a device, and wherein the surface geometry of each of the plurality of recesses is complementary to a first surface of a plurality of further substrates, wherein each of the plurality of further substrates comprises an alignment feature and a device chosen from photonic devices, electrical devices, and mechanical devices, such that contacting the alignment feature of each of the plurality of further substrates to the alignment features of each of the plurality of recesses permits each of the further substrates to fit into each of the plurality of recesses thereby permitting the devices of the plurality of recesses to be aligned with each of the plurality of devices of the plurality of further substrates.

24. An optical assembly comprising:
a first chip comprising a first surface comprising a first locator and a first device; a first chip sub-mount comprising a second surface comprising a second locator and a second device, wherein the first surface of the first chip fits into a recess in the second surface of the sub-mount when the first locator contacts the second locator.

25. An optical assembly according to claim 24, wherein the first and second devices are chosen from photonic devices, electronic devices, and mechanical devices.

26. An optical assembly according to claim 24, wherein the first chip sub-mount further comprises a plurality of recesses comprising a further locator, each recess arranged to accept at least one of a plurality of further chips, wherein each chip comprises a locator complementary to at least one of the further locators.

27. An optical assembly according to claim 26, further comprising:
a first substrate comprising the first chip and each of the plurality of further chips;
a second substrate comprising the first sub-mount.

28. A method of making an integrated optical assembly comprising:
forming a first structure and a first alignment feature on a first substrate;
forming a second structure and a second alignment feature on a second substrate, wherein the second structure and the second alignment feature are complementary in shape to the first structure and the first alignment feature, respectively, on the first substrate;
positioning a first device on the first substrate;
positioning a second device on the second substrate; and
contacting the first alignment feature of the first substrate to the second alignment feature of the second substrate thereby permitting the first device on the first substrate to be aligned with the second device on the second substrate.

29. An optical assembly comprising:
a first and a second mechanically matched substrates, each substrate comprising structures, wherein the structures on one substrate comprise shapes complementary to the structures on the other substrate, wherein at least one substrate comprises one or more clipgates for an optical component.

30. An optical assembly according to claim 29, wherein the structures comprise circuits or circuit elements.

31. An optical assembly according to claim 29, wherein said optical component is chosen from a fiber, a waveguide, a laser, a grating, or a detector.

32. A method of making an integrated optical assembly, said method comprising:
(a) fabricating structures on a first substrate;
(b) fabricating structures on a second substrate in shapes complementary to the structures on the first substrate, wherein at least one of said first and second substrates comprise a clipgate for an optical component;
(c) mechanically positioning an optical component in said clipgate;
(d) bringing said first and second substrates into face-to-face configuration such that the complementary shaped structures are aligned;
(e) physically contacting said first and second substrates; and
(f pressing the said first and second substrates together.

33. A method of making an integrated optical assembly of claim 32, further comprising:
providing a mechanical holding device, or adhesive bonding.

34. A method of making an integrated optical assembly of claim 32, wherein the assembly is cut to fabricate a plurality of isolated individual device components.

35. The method of making an integrated optical assembly of claim 32, wherein said fabricating of (a) and (b) are chosen from at least one of multilayer lithography, 3-D lithography, molding, embossing, stamping, replicating, and direct machining.

36. The method of making an integrated optical assembly of claim 32, wherein the structures on said first and second substrates comprise circuits or circuit elements.

37. An optical assembly according to claim 1, wherein the first substrate is made from a material chosen from at least one of glass, polymers, semiconductors, metals, and composites, and further wherein the second substrate is made from a material chosen from at least one of glass, polymers, semiconductors, metals, and composites.

38. An optical assembly according to claim 17, wherein the first substrate is made from a material selected from at least one of glass, polymers, semiconductors, metals, and composites, and further wherein the second substrate is made from a material selected from at least one of glass, polymers, semiconductors, metals, and composites.

39. An optical assembly according to claim 24, wherein the chip is made from a material selected from at least one of glass, polymers, semiconductors, metals, and composites, and further wherein the chip sub-mount is made from a material selected from at least one of glass, polymers, semiconductors, metals, and composites.
